(19) United States
(12) Patent Application Publication
(10) Pub. No.: US 2016/0268267 A1
(43) Pub. Date: Sep. 15, 2016

(54) SEMICONDUCTOR MEMORY DEVICE AND METHOD FOR MANUFACTURING THE SAME

(71) Applicant: Kabushiki Kaisha Toshiba, Minato-ku (JP)

(72) Inventors: Toshihiko IINUMA, Yokkaichi (JP); Masahiro KIYOTOSHI, Yokkaichi (JP)

(73) Assignee: Kabushiki Kaisha Toshiba, Minato-ku (JP)

(21) Appl. No.: 14/845,948

(22) Filed: Sep. 4, 2015

Related U.S. Application Data
(60) Provisional application No. 62/132,976, filed on Mar. 13, 2015.

(51) Int. Cl. H01L 27/115; H01L 21/3105

(52) U.S. Cl. CPC H01L 27/1157; H01L 27/11578; H01L 21/31051

(57) ABSTRACT

According to one embodiment, a semiconductor memory device includes a semiconductor substrate, a first electrode film formed on the semiconductor substrate, a second electrode film formed on the first electrode film, a first semiconductor member going through the first electrode film, a second semiconductor member going through the second electrode film and connected to the first semiconductor member, a first insulating layer provided between the first electrode film and the first semiconductor member, and a memory film provided between the second electrode film and the second semiconductor member and capable of storing charge. The first electrode film includes a silicon layer, and a metal layer provided on the silicon layer.

### CROSS-REFERENCE TO RELATED APPLICATIONS

This application is based upon and claims the benefit of priority from U.S. Provisional Patent Application 62/132,976, filed on Mar. 13, 2015; the entire contents of which are incorporated herein by reference.

### FIELD

Embodiments described herein relate generally to a semiconductor memory device and a method for manufacturing the same.

### BACKGROUND

Three-dimensional stacked flash memory devices in which memory cells are stacked on the surface of a substrate have been developed for some time now. Such technologies make far more efficient use of the surface area available on a substrate than planar two-dimensional semiconductor memory devices and have enabled a rapid increase in the number of memory cells that can be packed into a single semiconductor memory device. These types of three-dimensional stacked flash memory devices include, on a single substrate, a cell region in which memory cells are stacked three-dimensionally and a peripheral circuit region in which control circuits for the memory cells are formed.

### BRIEF DESCRIPTION OF THE DRAWINGS

FIG. 1 and FIG. 2 are cross-sectional views illustrating a semiconductor memory device according to an embodiment;

FIG. 3A to FIG. 22 are process cross-sectional views illustrating a method for manufacturing the semiconductor device according to the embodiment; and

FIG. 23 is a cross-sectional view illustrating a semiconductor memory device according to a comparative example.

### DETAILED DESCRIPTION

According to one embodiment, a semiconductor memory device includes a semiconductor substrate, a first electrode film formed on the semiconductor substrate, a second electrode film formed on the first electrode film, a first semiconductor member going through the first electrode film, a second semiconductor member going through the second electrode film and connected to the first semiconductor member, a first insulating layer provided between the first electrode film and the first semiconductor member, and a memory film provided between the second electrode film and the second semiconductor member and capable of storing charge. The first electrode film includes a silicon layer, and a metal layer provided on the silicon layer.

Various embodiments will be described hereinafter with reference to the accompanying drawings.

### Embodiments

First, an embodiment will be described.

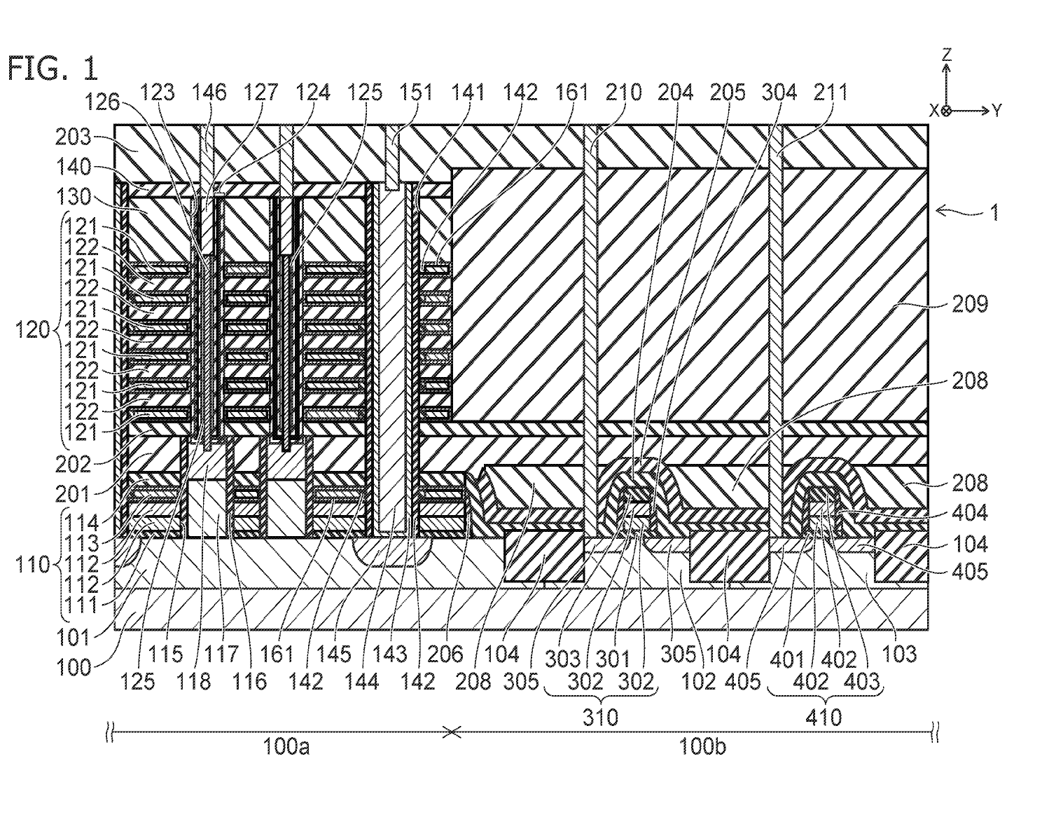

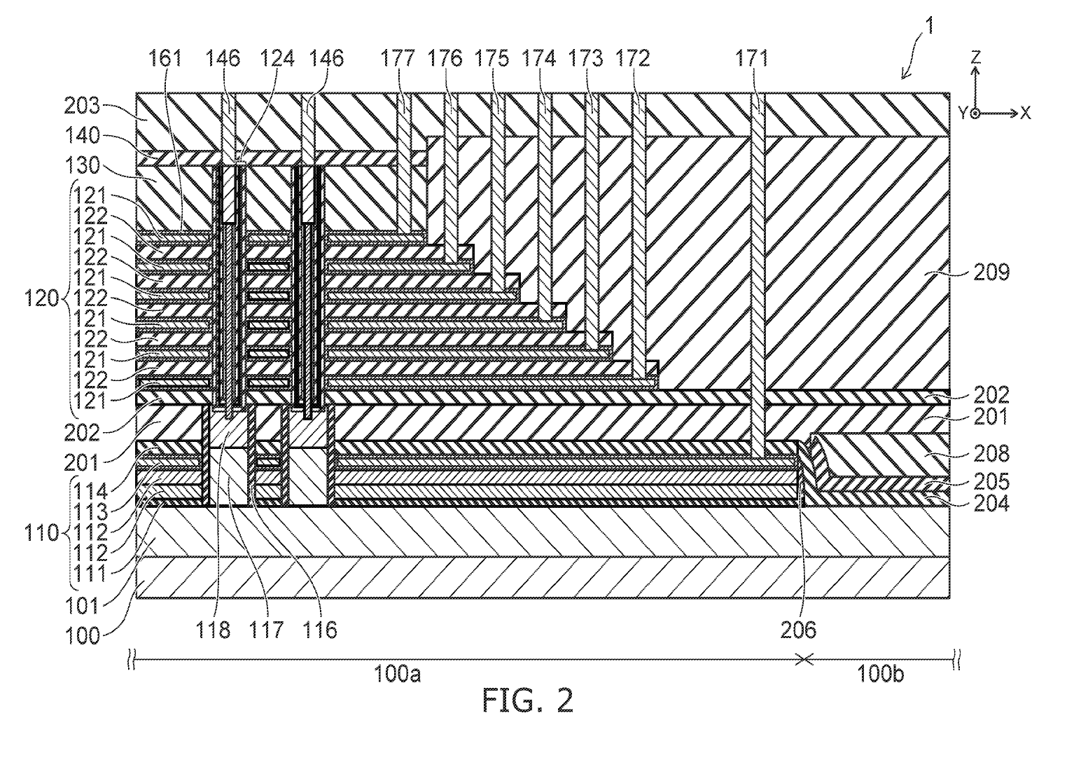

FIG. 1 and FIG. 2 are cross-sectional views illustrating a semiconductor memory device according to the embodiment, and show the cross sections orthogonal to one another.

In the patent specification, the following XYZ orthogonal coordinate system is introduced for convenience of explanation.

In this coordinate system, two mutually orthogonal directions that run parallel to the upper surface of a semiconductor substrate 100 are the X-direction and Y-direction. Moreover, the direction orthogonal to both the X-direction and Y-direction is the Z-direction.

As illustrated in FIG. 1 and FIG. 2, a semiconductor memory device 1 according to the embodiment includes a semiconductor substrate 100 which is divided into two regions: a cell region 100a in which stacked memory cells are arranged and a peripheral circuit region 100b in which peripheral circuits are arranged.

A p-type diffusion layer 101 is provided on the cell region 100a side of the semiconductor substrate 100. The p-type diffusion layer 101, an n-type diffusion layer 102, and a p-type diffusion layer 103 are provided on the peripheral circuit region 100b side of the semiconductor substrate 100.

A device isolation film 104 is provided at an upper layer portion between the p-type diffusion layer 101 and the n-type diffusion layer 102, at an upper layer portion between the n-type diffusion layer 102 and the p-type diffusion layer 103, and at an upper layer portion of the end portion of the p-type diffusion layer 103 in the Y-direction.

First, the structure provided in the cell region 100a will be described.

A first stacked part 110 is formed on top of the p-type diffusion layer 101 in the cell region 100a. The first stacked part 110 is formed by stacking, in order from bottom to top, an insulating film 111; two conductive layers 112 made from a silicon material that contains phosphorous (P) impurities, for example, as donors; a conductive layer 113 made from a metal material; and an insulating film 114. A metal material such as tungsten (W) may be used for the conductive layer 113. Moreover, the number of conductive layers 112 does not necessarily need to be two. A single conductive layer 112 or three or more conductive layers 112 may be used. The conductive layers 112 and 113 of the first stacked part 110 extend in the X-direction and function as a select gate electrode (a first electrode film).

An interlayer insulating film 201 is provided on top of the insulating film 114.

Furthermore, memory holes 115 (first through holes) are formed going through the interlayer insulating film 201 and the first stacked part 110. An insulating layer 116 is provided on the inner surface of each memory hole 115.

Inside the portion of each memory hole 115 that goes through the first stacked part 110, a semiconductor member 117 made from an intrinsic semiconductor material or a semiconductor material that contains a low concentration of p-type impurities, for example, is provided. On top of the semiconductor member 117, a conductive member 118 made from a silicon material that contains arsenic (As) impurities, for example, as donors is provided. In this way, a select transistor is formed within each memory hole 115.

An interlayer insulating film 202 is provided on top of the interlayer insulating film 201. A second stacked part 120 is formed on top of the interlayer insulating film 202.

The second stacked part 120 is formed by alternately stacking metal conductive layers 121 and insulating layers 122. A metal material such as tungsten (W) may be used for the conductive layers 121, for example. The conductive layers 121 extend in the X-direction and function as control gate electrodes. Moreover, the conductive layer 113 and the conductive layers 121 are made from the same material.

An insulating film 130 is provided on top of the second stacked part 120.

Through holes 123 (second through holes) are formed directly over the memory holes 115 and go through the insulating film 130, the second stacked part 120, and the interlayer insulating film 202.

The through holes 123 are formed connecting to the memory holes 115. A stacked film 124, (a memory film), is provided on the inner surface of each through hole 123. Each stacked film 124 includes a block insulating film made from a material such as silicon oxide, a charge storage film made from a material such as silicon nitride, and a tunnel insulating film made from a material such as silicon oxide. These films are stacked in order from the inner surface side of the memory holes 115 to form each stacked film 124. The block insulating film does not allow current to flow through (that is, substantially blocks current) when a voltage within the drive voltage range of the semiconductor memory device 1 is applied to that block insulating film. The charge storage film is capable of storing electric charges applied thereto. The tunnel insulating film normally functions as an insulator but allows a tunneling current to flow through when a prescribed voltage within the drive voltage range of the semiconductor memory device 1 is applied to that tunnel insulating film.

Moreover, an aluminum oxide film may also be formed on the inner surface side of each through hole 123. In this case, each stacked film 124 is provided on top of the respective aluminum oxide film.

In addition, a semiconductor layer 125 made from a material such as silicon is provided on the side surface of each stacked film 124 on the portion thereof that goes through the second stacked part 120. Furthermore, a semiconductor member 126 (a second semiconductor member) made from a material such as silicon is provided within the portion of each through hole 123 that goes through the second stacked part 120. The bottom end of each semiconductor member 126 goes through the stacked film 124 and the semiconductor layer 125 provided on the bottom surface of the respective through hole 123 and is connected to the conductive member 118 in the respective memory hole 115. Moreover, a conductive member 127 made from a silicon material that contains arsenic impurities, for example, as donors is provided in the portion of each through hole 123 that goes through the insulating film 130.

An insulating film 140 is provided on top of the insulating film 130. Furthermore, a through hole 141 is provided going through the insulating films 140 and 130, the second stacked part 120, the interlayer insulating films 202 and 201, and the first stacked part 110. An insulating film 142 made from a material such as silicon nitride is provided on the inner surface of the through hole 141. A conductive film 143 made from titanium (Ti) and titanium nitride (TiN) is provided on the side surface of the insulating film 142. The conductive film 143 is also provided on the bottom surface of the through hole 141.

A conductive member 144 made from a metal material such as tungsten (W), for example, is provided inside the through hole 141.

An n⁺ source layer 145 is provided in the upper layer portion of the p-type diffusion layer 101 directly below the through hole 141 and is connected to the conductive member 144.

Portions of the insulating film 142 that is provided inside the through hole 141 extend out and contact the through hole 141-side side surfaces of the conductive layers 113 and 121. The portions of the conductive layers 121 that do not contact the insulating film 142 are covered by dielectric layers 161 made using aluminum oxide films, for example. The side surfaces of the extending portions of the insulating film 142 are also covered by the dielectric layers 161.

An insulating film 203 is provided on top of the insulating film 140. Moreover, plugs 146 are provided directly above the conductive members 127 and go through the insulating film 203 and 140. The plugs 146 are connected to the conductive members 127. A plug 151 is provided directly above the conductive member 144 and goes through the insulating film 203. The plug 151 is connected to the conductive member 144.

Next, the structure provided in the peripheral circuit region 100b will be described.

On top of the n-type diffusion layer 102 in the peripheral circuit region 100b, an insulating film 301; two conductive layers 302 made from a silicon material that contains phosphorous impurities, for example, as donors; and an insulating layer 303 made from silicon nitride are provided in order from bottom to top. These layers are provided in an area directly above the area between the device isolation films 104 provided at both ends of the upper layer portion of the n-type diffusion layer 102 and are separated from those device isolation films 104. The insulating film 301, the two stacked bodies 302, and the insulating layer 303 form a stacked body 310.

The width (in the Y-direction) of the insulating film 301 of the stacked body 310 is greater than the widths (in the X-direction) of the conductive layers 302 and the insulating layer 303 provided on top of that insulating film 301. Two insulating films 304 are formed on top of the ends of the insulating film 301 and cover both side surfaces of the conductive layers 302 and the insulating layer 303. Two p⁺ regions 305 are provided in the upper layer portion of the n-type diffusion layer 102. Each p⁺ region 305 extends out from the respective end of the upper layer portion of the n-type diffusion layer 102 and contacts the lower surface of the respective end of the insulating film 301 provided on top of the n-type diffusion layer 102. The two p⁺ regions 305 are separated from one another. In this way, the stacked body 310, the n-type diffusion layer 102, and the p⁺ regions 305 form a transistor.

Moreover, on top of the p-type diffusion layer 103, an insulating film 401; two conductive layers 402 made from a silicon material that contains phosphorous impurities, for example, as donors; and an insulating layer 403 made from silicon nitride are provided in order from bottom to top. These layers are provided in an area directly above the area between the device isolation films 104 provided at both ends of the upper layer portion of the p-type diffusion layer 103 and are separated from those device isolation films 104. The insulating film 401, the two stacked bodies 402, and the insulating layer 403 form a stacked body 410. Two n⁺ regions 405 are provided in the upper layer portion of the p-type diffusion layer 103. Each n⁺ region 405 extends out from the respective end of the upper layer portion of the n-type diffusion layer 102 and contacts the lower surface of the respective end of the insulating film 401 provided on top of the p-type diffusion layer 103. The two n⁺ regions 405 are separated from one another.

In this way, the stacked body 410, the p-type diffusion layer 103, and the n⁺ regions 405 form a transistor.

Moreover, an insulating film 204 is provided over the entire peripheral circuit region 100b and covers the stacked bodies 310 and 410 as well as the insulating films 304 and 404 from the top. The insulating film 204 is a silicon oxide film, for example.

Furthermore, an insulating film 205 made from a material such as silicon nitride is provided so as to cover the insulating film 204 from the top. The insulating film 205 extends from above the portion of the p-type diffusion layer 101 in the peripheral circuit region 100b to above the p-type diffusion layer 102 and above the p-type diffusion layer 103.

Moreover, the portions of the insulating films 204 and 205 covering the stacked bodies 310 and 410 grow taller in the Z-direction and form mountain-shaped peaks.

On the p-type diffusion layer 101 of the peripheral circuit region 100b, the insulating film 111 of the first stacked part 110 is formed longer in the Y-direction than the conductive layers 112 and 113 and the insulating layer 114. An insulating film 206 is provided on top of the end of the insulating film 111 and covers the side surfaces of the conductive layers 112 and 113. The cell region 100a side end of the insulating film 204 covers the end face of the insulating film 111 as well as the insulating film 206. The end face of the insulating film 204 contacts the end face of the insulating film 114. The cell region 100a side end of the insulating film 205 covers the cell region 100a side end of the insulating film 204. Moreover, the insulating film 204 and the insulating film 205 formed on top of the insulating film 204 form a valley shape at the locations where the lower surface of the insulating film 204 contacts the p-type diffusion layers 101 and 103 and the n-type diffusion layer 102. An insulating film 208 is provided inside the valley-shaped portions of the insulating film 205.

An interlayer insulating film 201 and an interlayer insulating film 202 are provided on top of the insulating film 208. These interlayer insulating films 201 and 202 are the same interlayer insulating films provided in the cell region 100a.

An insulating member 209 is provided on top of the interlayer insulating film 202 in the peripheral circuit region 100b. Moreover, an insulating layer 203 is provided on top of the insulating member 209. This insulating layer 203 is the same insulating film provided in the cell region 100a. Plugs 210 and 211 are formed in the peripheral circuit region 100b and go through the insulating film 203, the insulating member 209, the interlayer insulating films 202 and 201, the insulating film 208, and the insulating films 205 and 204. The end of the plug 210 contacts the p⁺ region 305 provided in the cell region 100a side of the upper layer of the n-type diffusion layer 102. The bottom end of the plug 211 contacts the n⁺ region 405 provided in the cell region 100a side of the p-type diffusion layer 103.

Moreover, as illustrated in FIG. 2, the first stacked part 110 and the second stacked part 120 extend in the X-direction. The conductive layer 113 of the first stacked part 110 and the conductive layers 121 of the second stacked part 120 become progressively shorter in the X-direction moving from the bottom layer of the semiconductor memory device to the top layer. Furthermore, in the second stacked part 120, each insulating layer 122 is approximately equal in length to the conductive layer 121 directly below. In addition, the insulating member 209 is provided on top of the portion of the interlayer insulating film 202 not covered by the second stacked part 120. The insulating member 209 also covers the stepwise portions of the insulating layers 122 where the conductive layers 121 are not provided. The insulating film 203 is provided on top of the insulating member 209.

Moreover, plugs 171, 172, 173, 174, 175, 176, and 177 are connected, respectively, to the X-direction end of the conductive layer 113 of the first stacked part 110 and the X-direction ends of the conductive layers 121 of the second stacked part 120. When viewed from the Z-direction, the ends of the conductive layers to which the plugs 171, 172, 173, 174, 175, 176, and 177 are connected do not overlap.

Furthermore, the plug 171 goes through the insulating film 203, the insulating member 209, the interlayer insulating films 202 and 201, and the insulating film 114 and is connected to the end of the conductive layer 113. The plug 172 goes through the insulating film 203, the insulating member 209, and one of the insulating layers 122 and is connected to the end of the lowermost conductive layer 121 of the second stacked part 120. The plug 173 goes through the insulating film 203, the insulating member 209, and one of the insulating layers 122 and is connected to the end of the conductive layer 121 one layer above the lowermost conductive layer 121 of the second stacked part 120. The plug 174 goes through the insulating film 203, the insulating member 209, and one of the insulating layers 122 and is connected to the end of the conductive layer 121 two layers above the lowermost conductive layer 121 of the second stacked part 120. The plug 175 goes through the insulating film 203, the insulating member 209, and one of the insulating layers 122 and is connected to the end of the conductive layer 121 three layers above the lowermost conductive layer 121 of the second stacked part 120. The plug 176 goes through the insulating film 203, the insulating member 209, and one of the insulating layers 122 and is connected to the end of the conductive layer 121 four layers above the lowermost conductive layer 121 of the second stacked part 120. The plug 177 goes through the insulating film 203 and the insulating films 140 and 130 and is connected to the end of the uppermost conductive layer 121 of the second stacked part 120.

The insulating film 111 of the first stacked part 110 extends out farther in the X-direction than the conductive layers 112 and 113 and the insulating film 114 provided on top of the insulating film 111. The insulating film 206 is provided on the X-direction side end of the insulating film 111 and covers the side surfaces in the X-direction of the conductive layers 112 and 113. Moreover, the insulating film 204 is provided on top of the p-type diffusion layer 101 and covers the side surface in the X-direction of the insulating film 111 as well as the side surfaces in the X-direction of the insulating film 206 and the insulating film 114. This end of the insulating film 204 protrudes upwards in a half parabola shape. The insulating film 205 is provided on top of the insulating film 204. The end of the insulating film 205 also protrudes upwards in a half parabola shape. The insulating film 206 is provided on top of the insulating film 204.

Next, a manufacturing method for the semiconductor memory device according to the embodiment will be described.

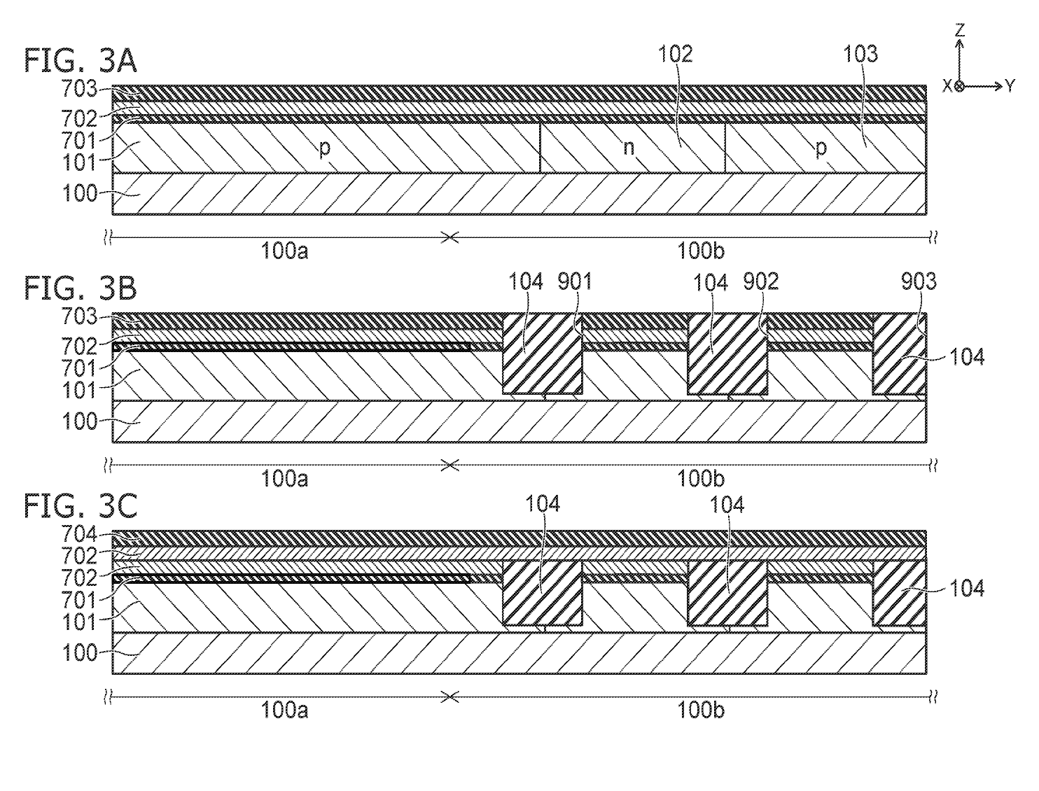

FIGS. 3A to 22 are process cross-sectional views illustrating a method for manufacturing the semiconductor device according to the embodiment.

First, as illustrated in FIG. 3A, impurities that function as acceptors are selectively injected into the upper layer of a semiconductor substrate 100 to form p-type diffusion layers 101 and 103. The p-type diffusion layer 101 is formed covering the entire cell region 100a and a cell region 100a side region of the peripheral circuit region 100b. The p-type diffusion layer 103 is formed in one portion of the peripheral circuit region 100b. Moreover, impurities that function as donors are selectively injected into the upper layer of the semiconductor substrate 100 to form an n-type diffusion layer 102. The n-type diffusion layer 102 is formed in the other portion of the peripheral circuit region 100b.

Next, an insulating film 701 is formed on top of the p-type diffusion layers 101 and 103 and on top of the n-type diffusion layer 102, and a conductive layer 702 is formed on top of the insulating film 701. An insulating film 703 made from a material such as silicon nitride is formed on top of the conductive layer 702.

Next, as illustrated in FIG. 3B, an anisotropic etching process such as reactive ion etching (RIE) is used to form trenches 901, 902, and 903 that go through the insulating film 703, the conductive layer 702, and the insulating film 701 and reach down into the p-type diffusion layer 101, the n-type diffusion layer 102, and the p-type diffusion layer 103. The trench 901 is formed in a portion that includes the boundary between the p-type diffusion layer 101 and the n-type diffusion layer 102 and in the region directly above. Moreover, the trench 902 is formed in a portion that includes the boundary between the n-type diffusion layer 102 and the p-type diffusion layer 103 and in the region directly above. Furthermore, the trench 903 is formed in the end portion in the Y-direction of the p-type diffusion layer 103 and in the region directly above.

Next, device isolation films 104 are formed inside the trenches 901, 902, and 903.

Then, as illustrated in FIG. 3C, the insulating film 703 is removed using a wet etching process. At this time, the device isolation films 104 are also etched back such that the top surfaces thereof are even with the top surface of the conductive layer 702. Then, another conductive layer 702 is formed over the entire surface of the substrate, and an insulating layer 704 made from a material such as silicon nitride is formed on top of the new conductive layer 702.

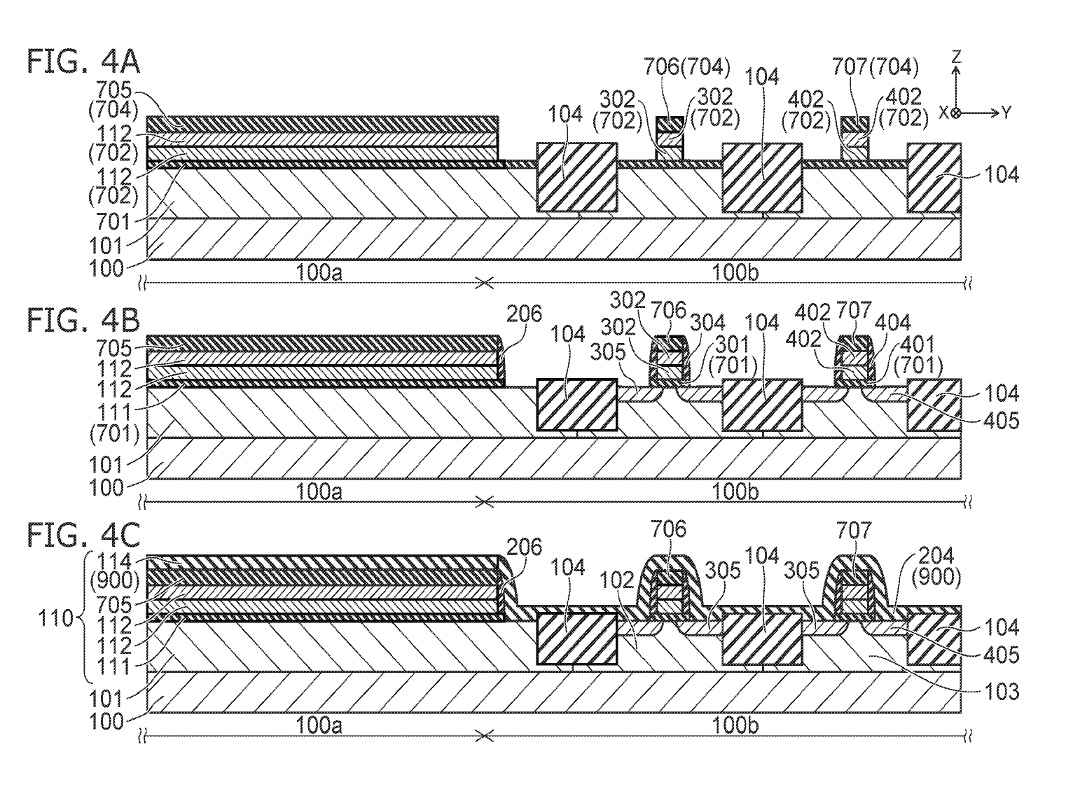

Next, as illustrated in FIG. 4A, an anisotropic etching process such as RIE is used to selectively remove portions of the stacked body that includes the insulating layer 704 and the conductive layers 702 and leave that stacked body remaining in the cell region 100a and in the region directly above the center of the n-type diffusion layer 102 as well as in the region directly above the center of the p-type diffusion layer 103.

In this way, in the cell region 100a, the conductive layers 702 formed on top of the insulating film 701 become the two conductive layers 112, and the insulating layer 704 formed thereon becomes an insulating film 705. Moreover, in the region directly above the center of the n-type diffusion layer 102, the conductive layers 702 formed on top of the insulating film 701 become the two conductive layers 302, and the insulating layer 704 formed thereon becomes an insulating film 706. Furthermore, in the region directly above the center of the p-type diffusion layer 103, the conductive layers 702 formed on top of the insulating film 701 become the two conductive layers 402, and the insulating layer 704 formed thereon becomes an insulating film 707. In this way, the conductive layers 112 and the insulating layer 705 form a second stacked body, and the conductive layers 302 and the insulating layer 706 as well as the conductive layers 402 and the insulating layer 707 each form an instance of a first stacked body.

Next, as illustrated in FIG. 4B, an insulating film is formed covering the entire substrate. Then, the entire surface of the substrate is etch-backed. This process leaves a portion of the insulating film formed on top of the insulating film 701 remaining on the side surfaces of the conductive layers 112 and the insulating film 705 and on the side surfaces of the conductive layers 302 and the insulating film 706 as well as on the side surfaces of the conductive layers 402 and the insulating film 707.

Next, the entire surface is etched. In this way, the portion of the insulating film 701 directly below the conductive layers 112 becomes the insulating film 111, and the portion of the insulating film 701 directly below the conductive layers 302 becomes the insulating film 301. Moreover, the portion of the insulating film 701 directly below the conductive layers 402 becomes the insulating film 401.

At this time, the portion of the insulating film left remaining, after the etch-back process is performed on the entire surface of the substrate, on the end of the insulating film 111 where the conductive layers 112 are not formed becomes the insulating film 206. This insulating film 206 covers the side surfaces of the two conductive layers 112 and the insulating film 705. Moreover, the portions of the insulating film left remaining on the ends of the insulating film 301 where the conductive layers 302 are not formed become the insulating films 304. These insulating films 304 cover the side surfaces of the two conductive layers 302 and the side surfaces of the insulating film 706. Furthermore, the portions of the insulating film left remaining on the ends of the insulating film 401 where the conductive layers 402 are not formed become the insulating films 404. These insulating films 404 cover the side surfaces of the two conductive layers 402 and the side surfaces of the insulating film 707.

Next, an ion implantation process in which impurities are implanted into the n-type diffusion layer 102 and the p-type diffusion layer 103 and in which all of the elements stacked onto the n-type diffusion layer 102 and the p-type diffusion layer 103 serve as a mask is performed. This process forms the p⁺ regions 305 at both ends of the upper portion of the n-type diffusion layer 102. This process also forms the n⁺ regions 405 at both ends of the upper portion of the p-type diffusion layer 103.

Next, as illustrated in FIG. 4C, an insulating film 900 is formed covering the cell region 100a and the peripheral circuit region 100b. In the cell region, this insulating film 900 becomes the insulating film 114 and is formed on top of the insulating film 705. Moreover, in the peripheral circuit region 100b, this insulating film 900 becomes the insulating film 204. Furthermore, the portions of the insulating film 204 that covers the stacked body that includes the insulating film 301, the two conductive layers 302, and the insulating film 706 and the stacked body that includes the insulating film 401, the two conductive layers 402, and the insulating film 707 are formed in mountain shapes. In this way, in the cell region 100a the insulating films 111, 705, and 114 and the two conductive layers 112 form the first stacked part 110.

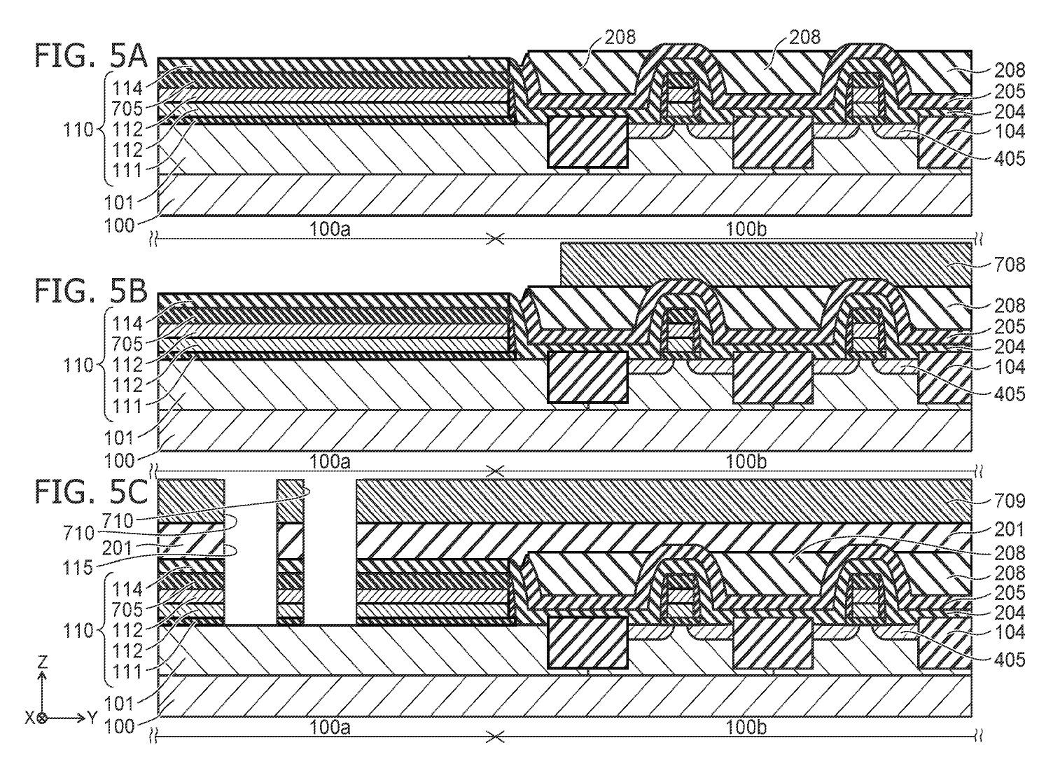

Next, as illustrated in FIG. 5A, an insulating film 205 is formed covering the insulating film 204. Then, an insulating film 208 is formed filling the valley-shaped portions of the insulating film 205. Next, a planarization process such as chemical mechanical polishing (CMP) is performed with the insulating film 205 serving as a stopper to planarize the upper surface of the insulating film 208. This process exposes the insulating film 205 across the entire cell region 100a. Moreover, in the peripheral circuit region 100b, this process exposes the portions of the insulating film 205 directly above the insulating films 706 and 707, leaving the other regions covered by the insulating film 208.

Next, as illustrated in FIG. 5B, a mask 708 is provided on the upper surface of the insulating film 208. Then, the entire surface is etched. This selectively removes the portions of the insulating film 205 that are not covered by the insulating film 208 or the mask 708. Next, the mask 708 is removed.

Then, as illustrated in FIG. 5C, an interlayer insulating film 201 is formed covering the entire cell region 100a and peripheral circuit region 100b. After the upper surface of the interlayer insulating film 201 is planarized, a mask 709 is formed on top of the interlayer insulating film 201.

Next, in the cell region 100a, openings 710 are formed in the mask 709. Then, the memory holes 115 are formed beneath the openings 710 by etching. The memory holes 115 go through the interlayer insulating film 201 and the first stacked part 110.

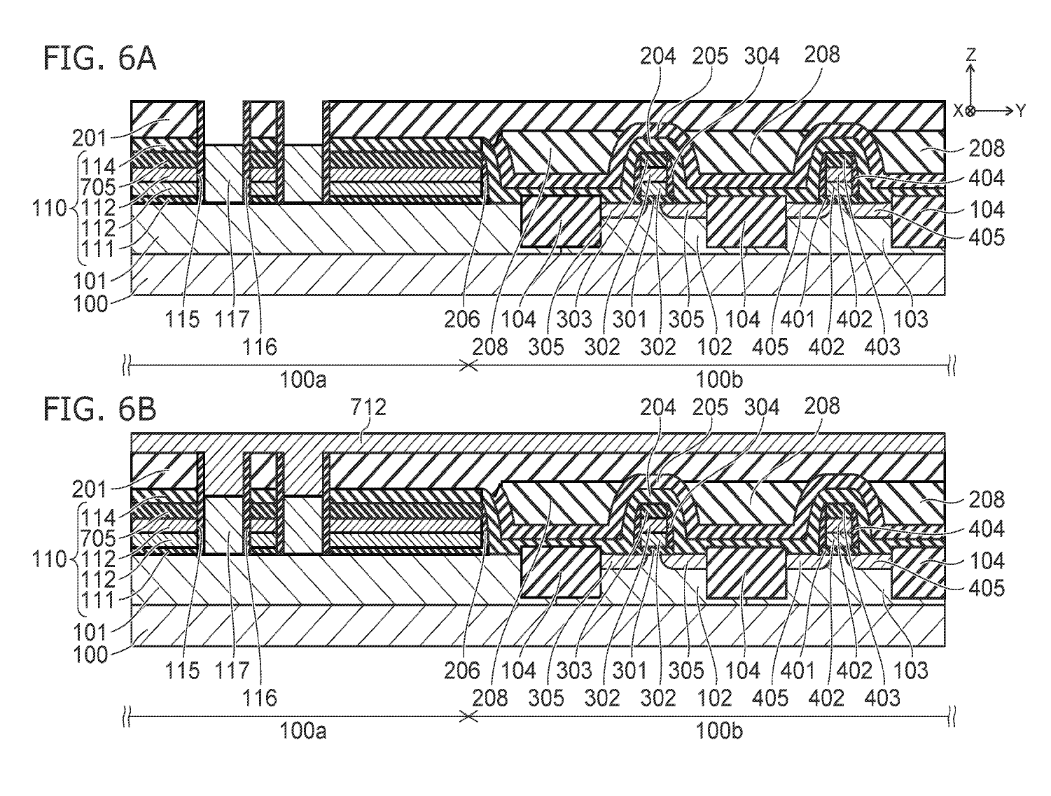

Next, as illustrated in FIG. 6A, the mask 709 is removed (see FIG. 5C). Then, an insulating material is deposited over the entire cell region 100a. This process forms an insulating layer 116 on the inner surface of each memory hole 115. Next, the entire surface is etch-backed to remove the portions of the insulating layer 116 on top of the interlayer insulating film 201 and on the bottom surface of the memory holes 115. Then, a semiconductor material such as silicon is deposited to form a semiconductor member 117 (a first semiconductor member) within the portion of each memory hole 115 that goes through the first stacked part 110.

Next, as illustrated in FIG. 6A, a conductive film 712 is formed on top of the interlayer insulating film 201. The conductive film 712 fills the upper portions of the memory holes 115. The conductive film 712 is formed using a silicon material that contains arsenic (As) impurities, for example, as donors.

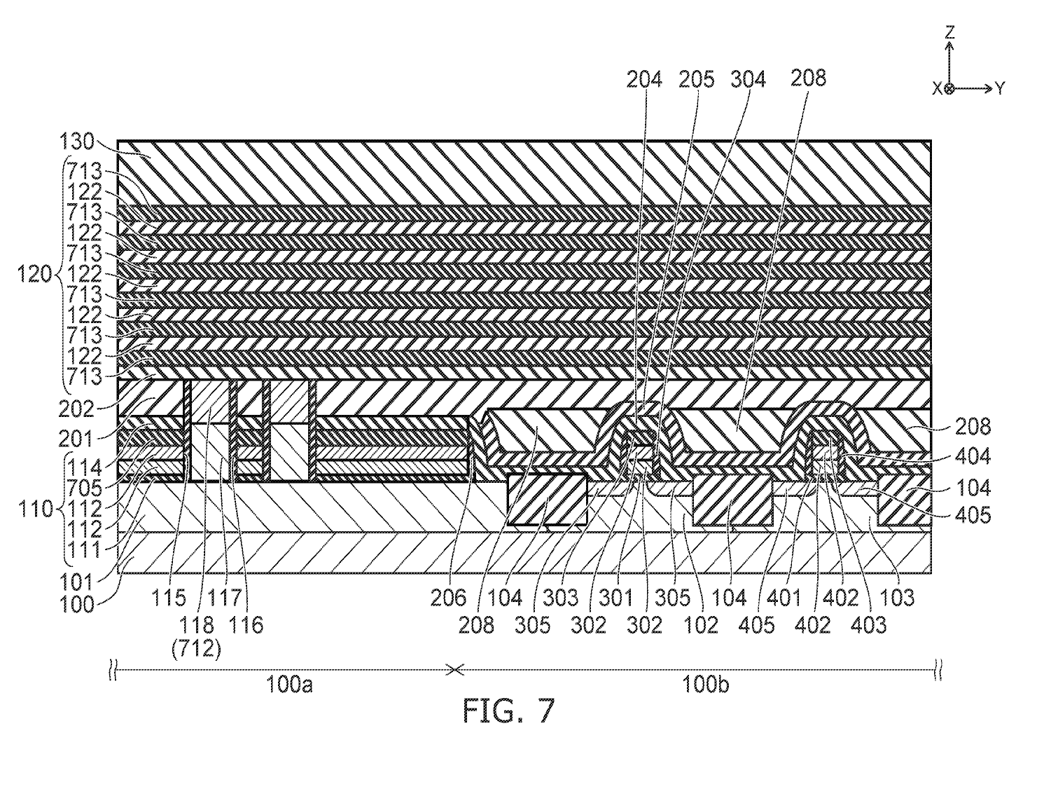

Next, as illustrated in FIG. 7, the portion of the conductive film 712 on top of the interlayer insulating film 201 is removed. At this time, the portions of the conductive film 712 filling the memory holes 115 remain. In this way, a conductive member 118 is formed on top of the semiconductor member 117 in each memory hole 115.

Next, an interlayer insulating film 202 is formed on top of the interlayer insulating film 201 and the conductive members 118. On top of the interlayer insulating film 202, insulating films 713 made from silicon nitride and insulating layers 122 made from silicon oxide are stacked in alternation, for example, to form the second stacked part 120 (a third stacked body). The combined number of insulating films 713 and insulating layers 122 in the second stacked part 120 is 11, for example. An insulating film 130 is formed on top of the second stacked part 120.

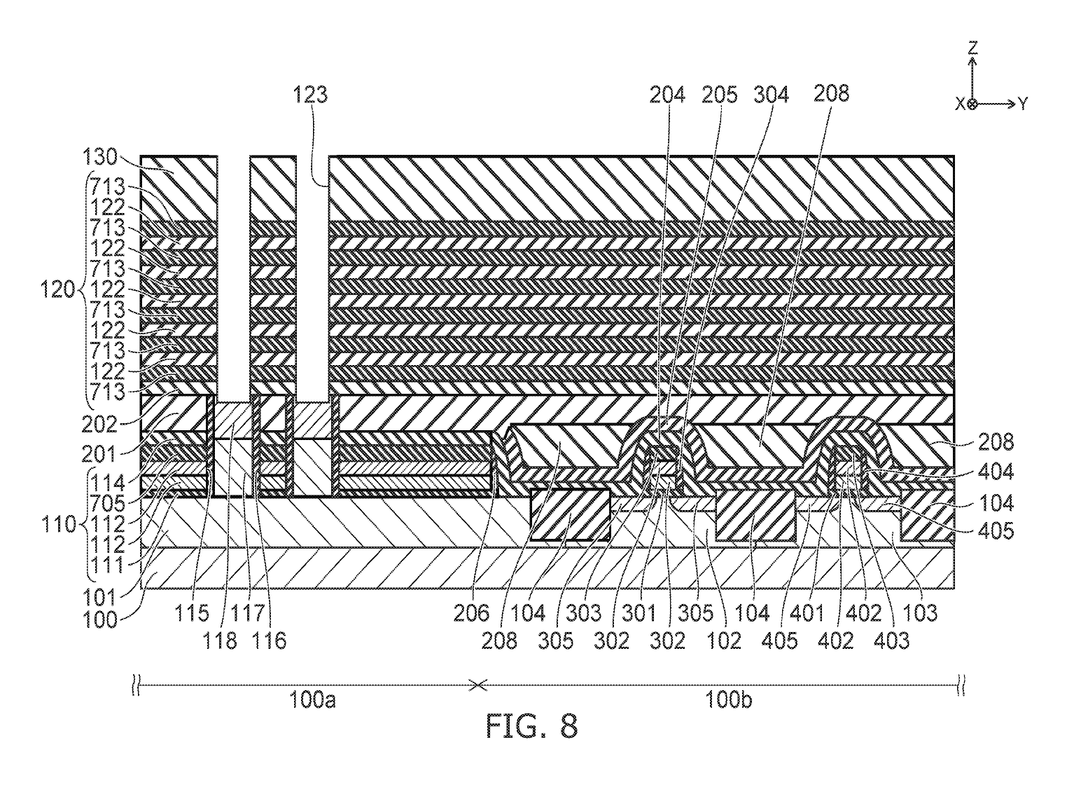

Next, as illustrated in FIG. 8, through holes 123 are formed in the regions directly above the memory holes 115. The through holes 123 go through the insulating film 130, the second stacked part 120, and the interlayer insulating film 202 and reach the conductive members 118 in the memory holes 115.

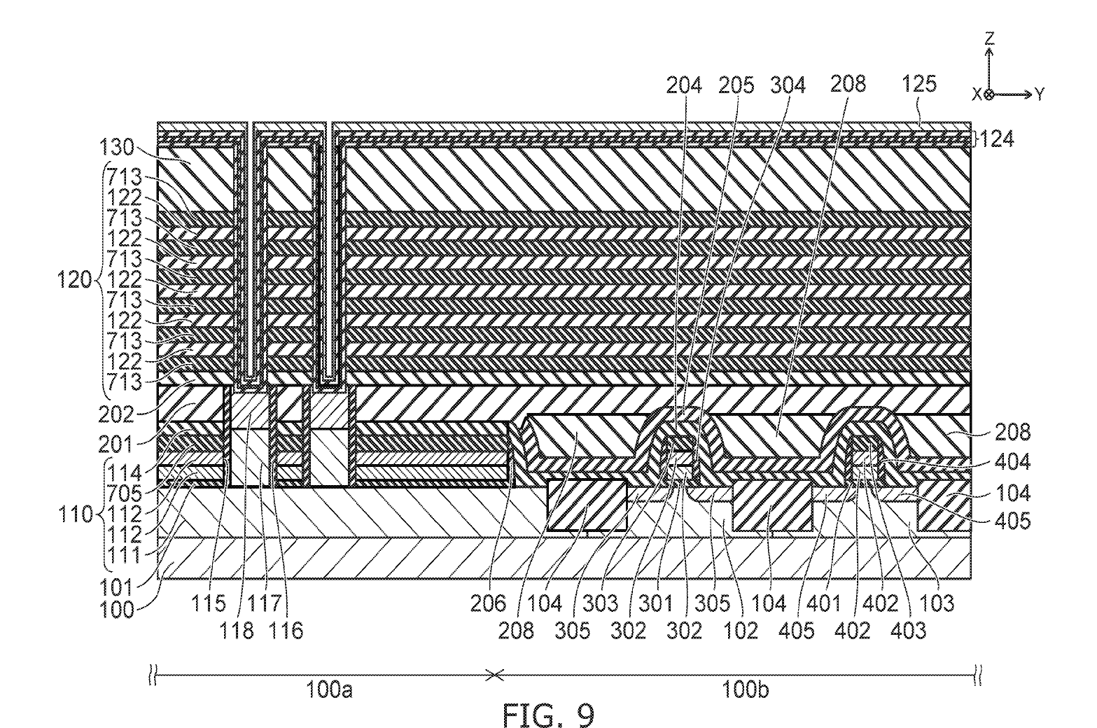

Next, as illustrated in FIG. 9, a stacked film 124 in which a block insulating film made from a material such as silicon oxide, a charge storage film made from a material such as silicon nitride, and a tunnel insulating film made from a material such as silicon oxide are stacked in order is formed on top of the insulating film 130. Alternatively, a stacked film 124 may be formed after an aluminum oxide film is formed on top of the insulating film 130.

A semiconductor layer 125 made from a material such as silicon is formed on top of the stacked film 124. The stacked film 124 and the semiconductor layer 125 also cover the inner surfaces of the through holes 123.

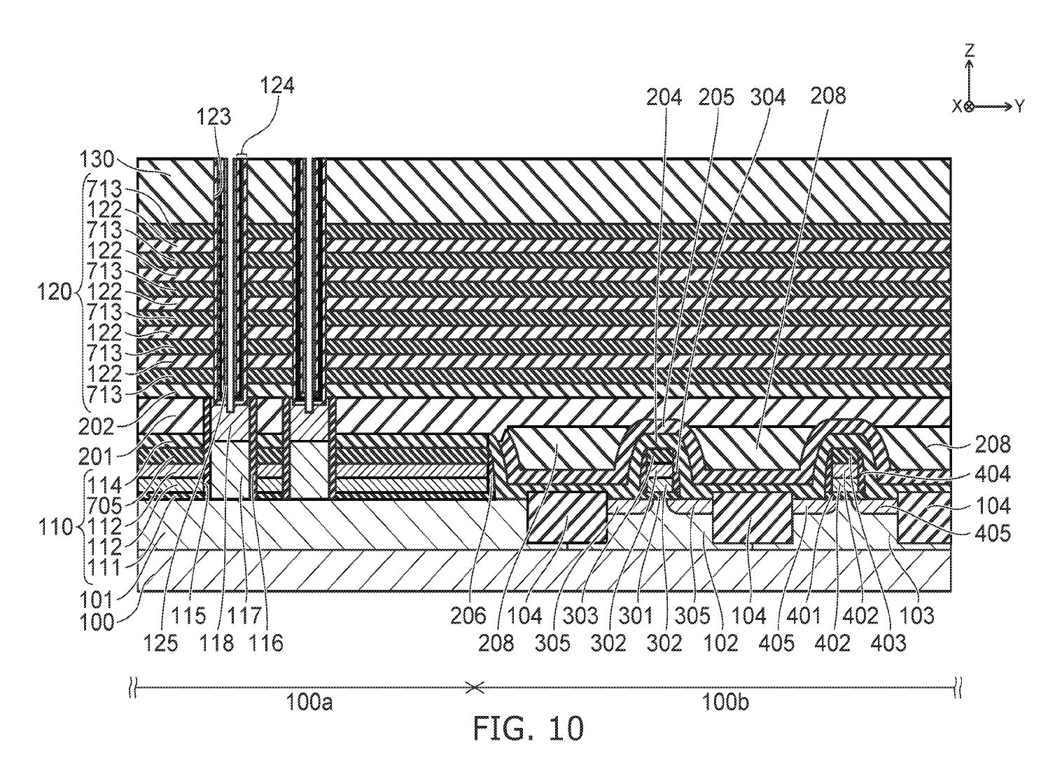

Next, as illustrated in FIG. 10, an RIE process is used to form through holes 714 that go through the stacked film 124 and the semiconductor layer 125 provided on the bottom surfaces of the through holes 123. The through holes 714 is formed so as to reach the upper portions of the conductive members 118. Moreover, the portions of the stacked film 124 and the semiconductor layer 125 on top of the insulating film 130 are removed by this RIE process. This process leaves only the portions of the stacked film 124 and the semiconductor layer 125 inside the through holes 123. In this way, the stacked film 124 and the semiconductor layer 125 are formed covering the inner surfaces of the through holes 123.

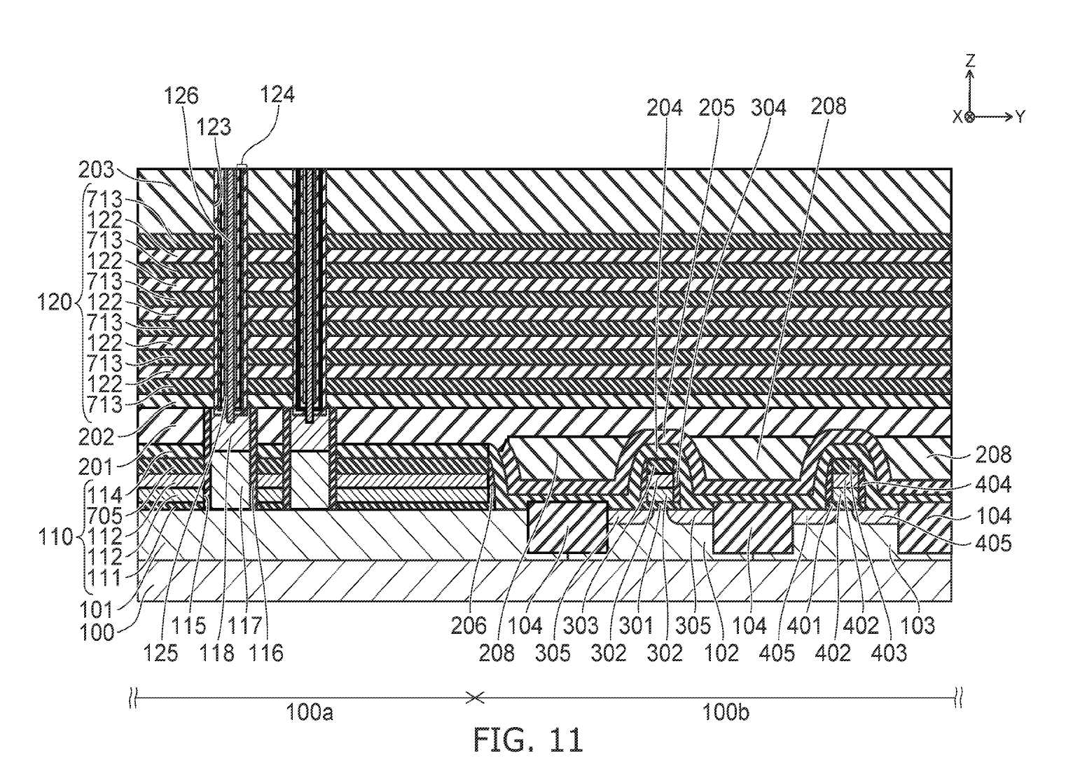

Next, as illustrated in FIG. 11, semiconductor members 126 are formed inside the through holes 123 and 714.

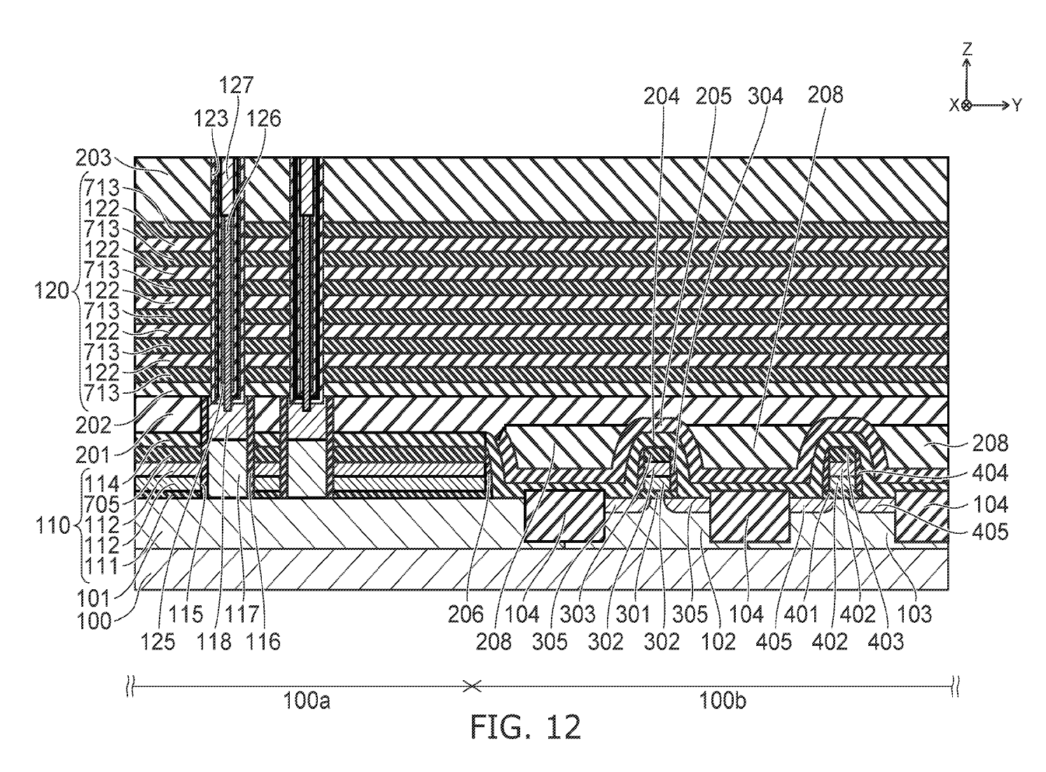

Then, as illustrated in FIG. 12, an etching process is performed to etch back the upper portions of the semiconductor layer 125 and the semiconductor members 126 in each through hole 123, thereby forming recesses. Conductive members 127 are formed inside these recesses. These recesses are equal in height to the portions of the through holes 123 going through the insulating film 203.

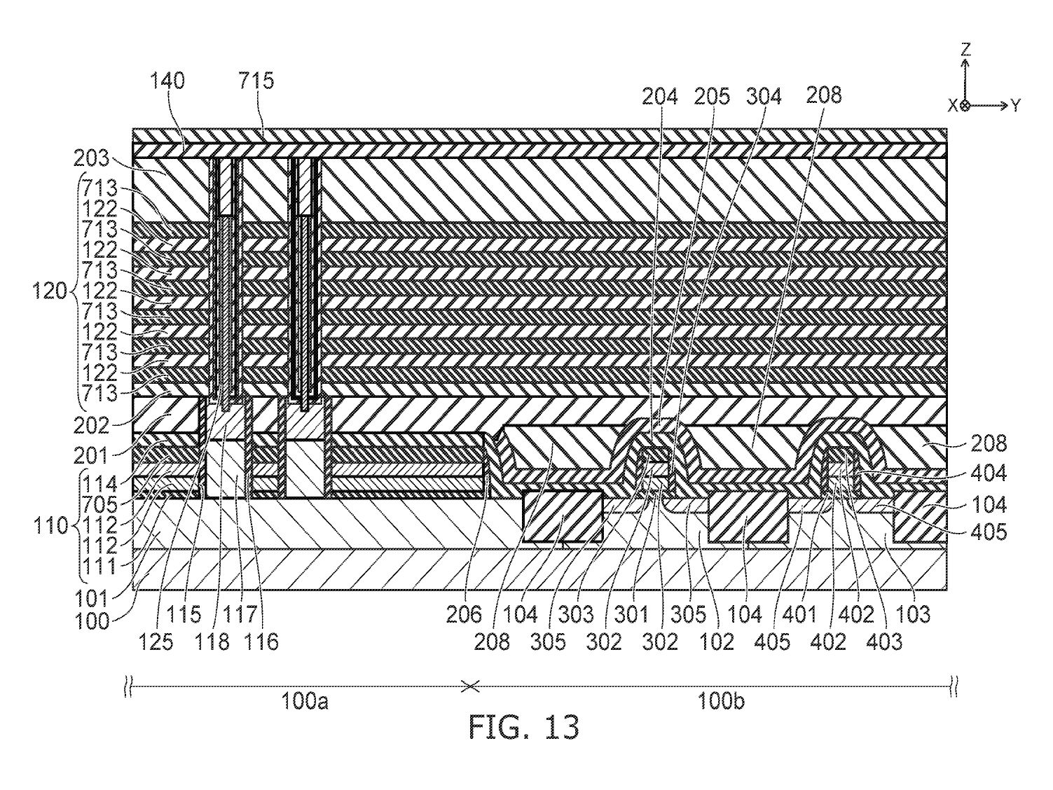

Next, as illustrated in FIG. 13, an insulating film 140 is formed on top of the insulating film 130, and an insulating film 715 is formed on top of the insulating film 140.

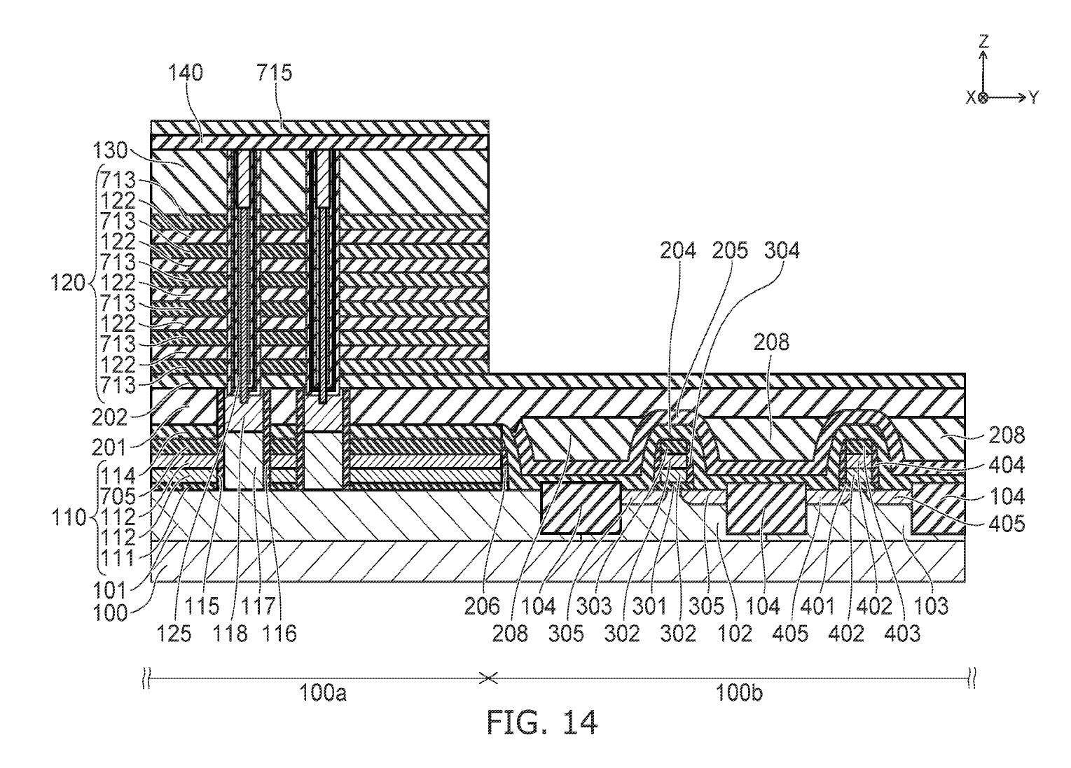

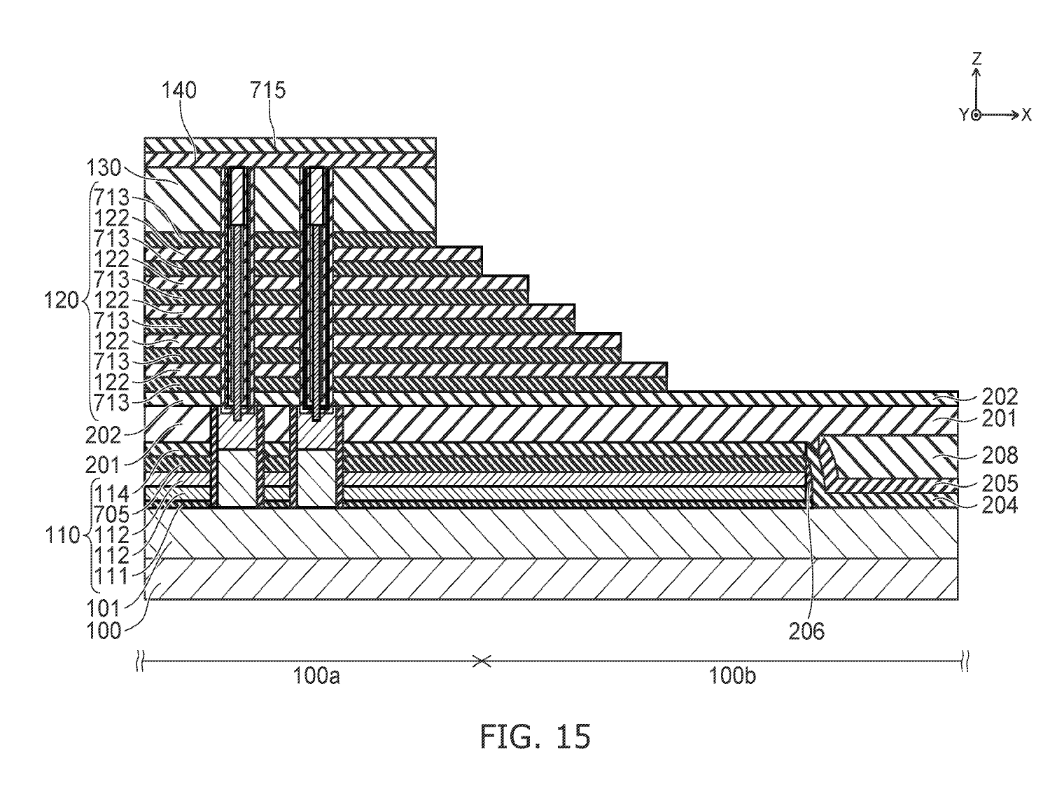

FIGS. 14 and 15 are mutually orthogonal cross-sectional views of the substrate in the same process.

Next, as illustrated in FIG. 14 and FIG. 15, the portions of the second stacked part 120 and the insulating films 130, 140, and 715 in the peripheral circuit region 100b are removed. At this time, the second stacked part 120 and the insulating films 130 and 715 in the cell region 100a are left remaining.

Here, the second stacked part 120 extends in the X-direction, and process is performed such that the insulating films 713 of the second stacked part 120 become progressively shorter in the X-direction moving from the bottom layer of the semiconductor memory device to the top layer. Furthermore, in the second stacked part 120, each insulating layer 122 is approximately equal in length in the X-direction to the insulating film 713 directly below. The insulating films 140 and 715 on top of the second stacked part 120 are approximately equal in length in the X-direction to the uppermost insulating film 713 of the second stacked part 120.

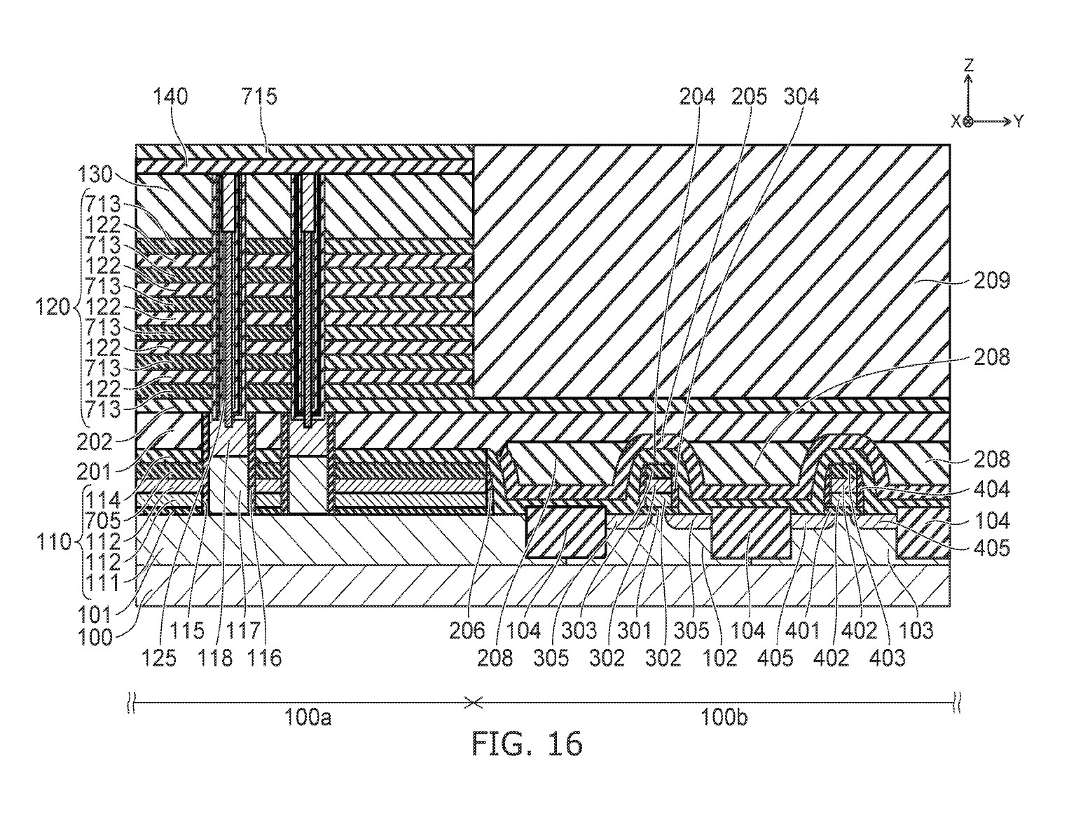

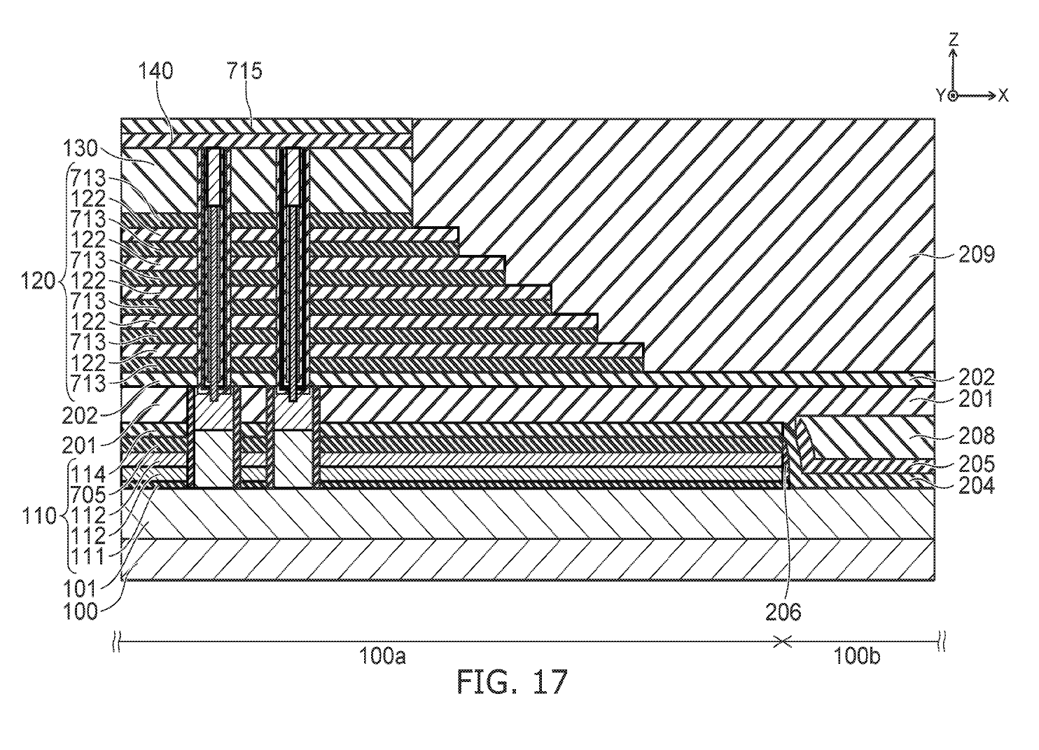

FIG. 16 and FIG. 17 are mutually orthogonal cross-sectional views of the substrate in the same process.

Next, as illustrated in FIG. 16 and FIG. 17, an insulating member 209 is formed on top of the interlayer insulating film 202 in the peripheral circuit region 100b. The insulating member 209 on top of the interlayer insulating film 202 is also formed beside the second stacked part 120, thereby covering the stair-shaped ends of the second stacked part 120. The upper surface of the insulating member 209 is even with the upper surface of the insulating layer 715 in the Z-direction.

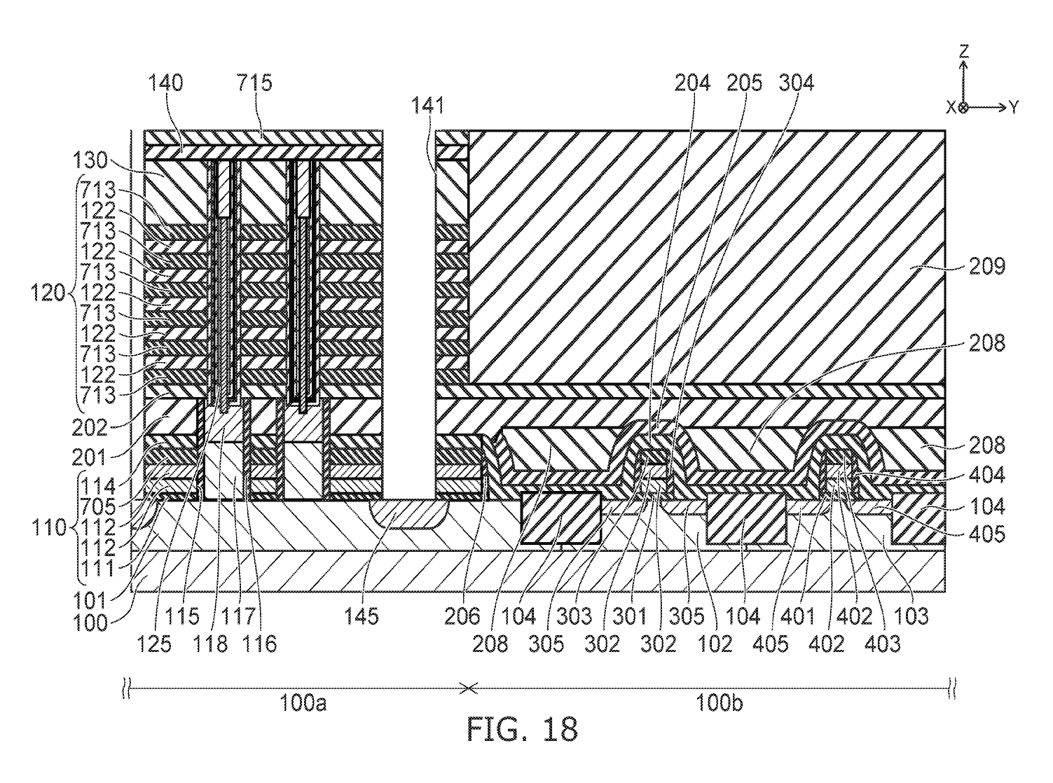

Next, as illustrated in FIG. 18, a through hole 141 is formed in the cell region 100a. The through hole 141 goes through the insulating films 715, 140, 130; the second stacked part 120; the interlayer insulating films 202 and 201; and the first stacked part 110 and reaches the p-type diffusion layer 101. Moreover, impurities are ion-implanted as donors through the through hole 141 into the bottom surface thereof to form an n⁺ source layer 145 in the upper surface of the p-type diffusion layer 101.

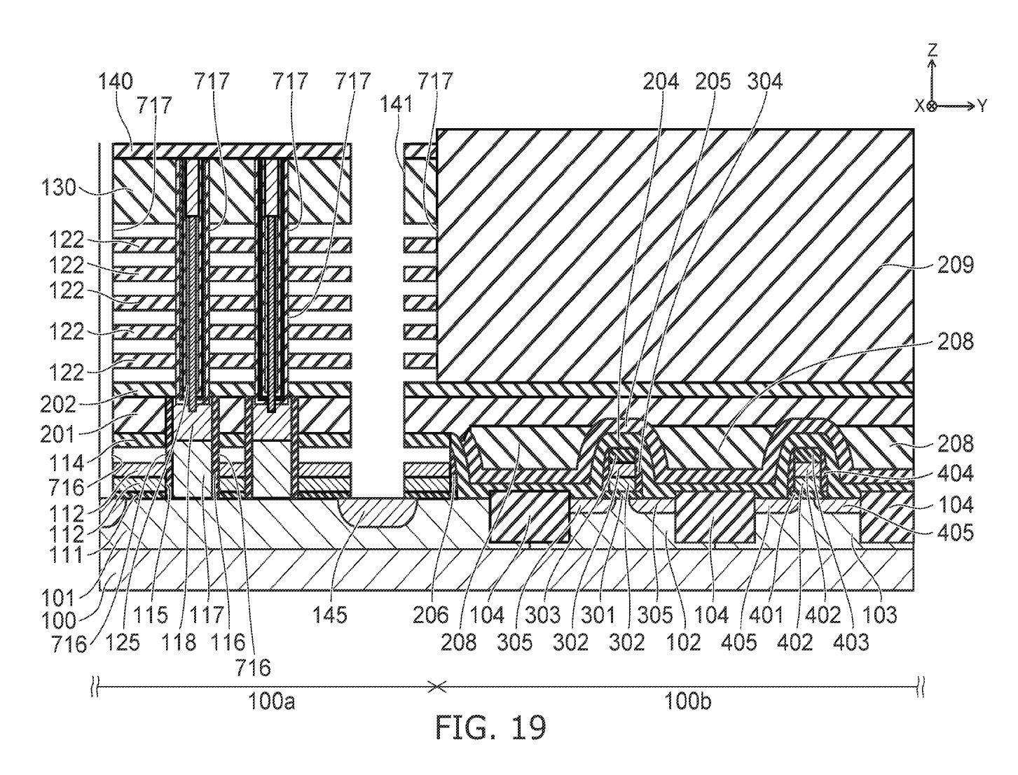

Next, as illustrated in FIG. 19, the insulating films 705, 713, and 715 are removed using a wet etching process using heated phosphoric acid, for example. This process creates cavities 716 where the insulating film 705 used to be formed and also creates cavities 717 where the insulating films 713 used to be formed.

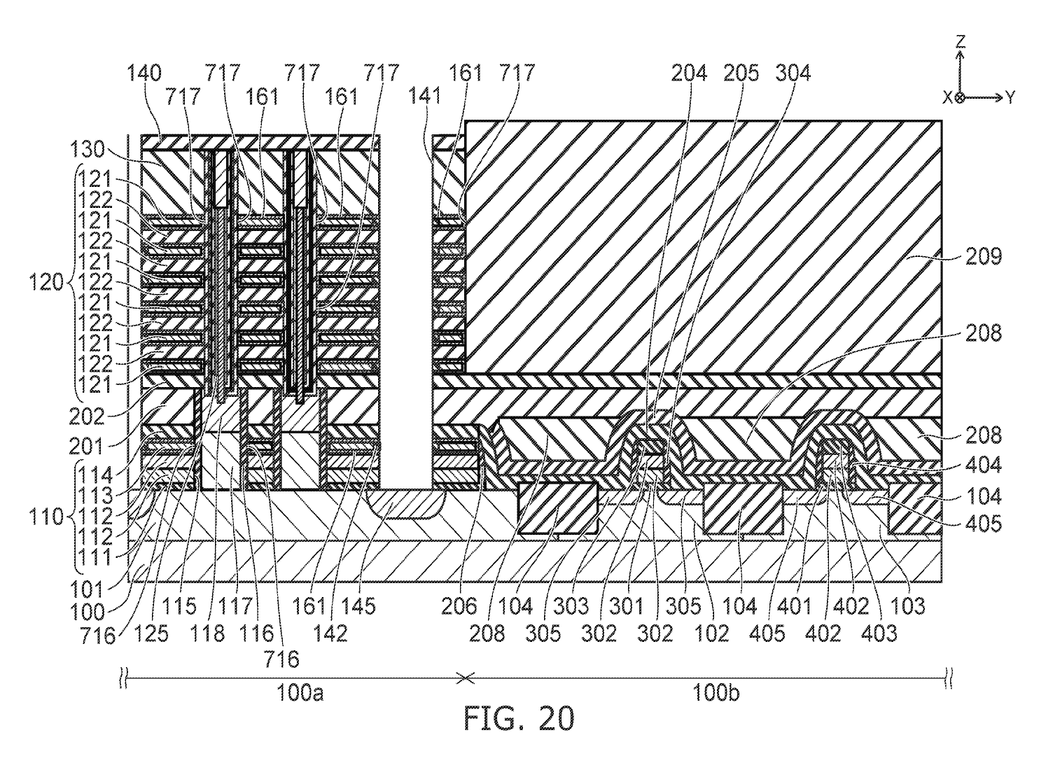

Next, as illustrated in FIG. 20, dielectric layers 161 made from aluminum oxide films, for example, are formed on the inner surfaces of all of the cavities 716 and 717. Then, conductive layers 113 made from tungsten, for example, are formed within all of the cavities 716 and 717. Note that after forming the dielectric layers 161 made from aluminum oxide, for example, on the inner surfaces of all of the cavities 716 and 717, a barrier metal such as titanium nitride, for example, may be formed on top of the dielectric layers 161 before filling the cavities 716 and 717 with the tungsten conductive films 113.

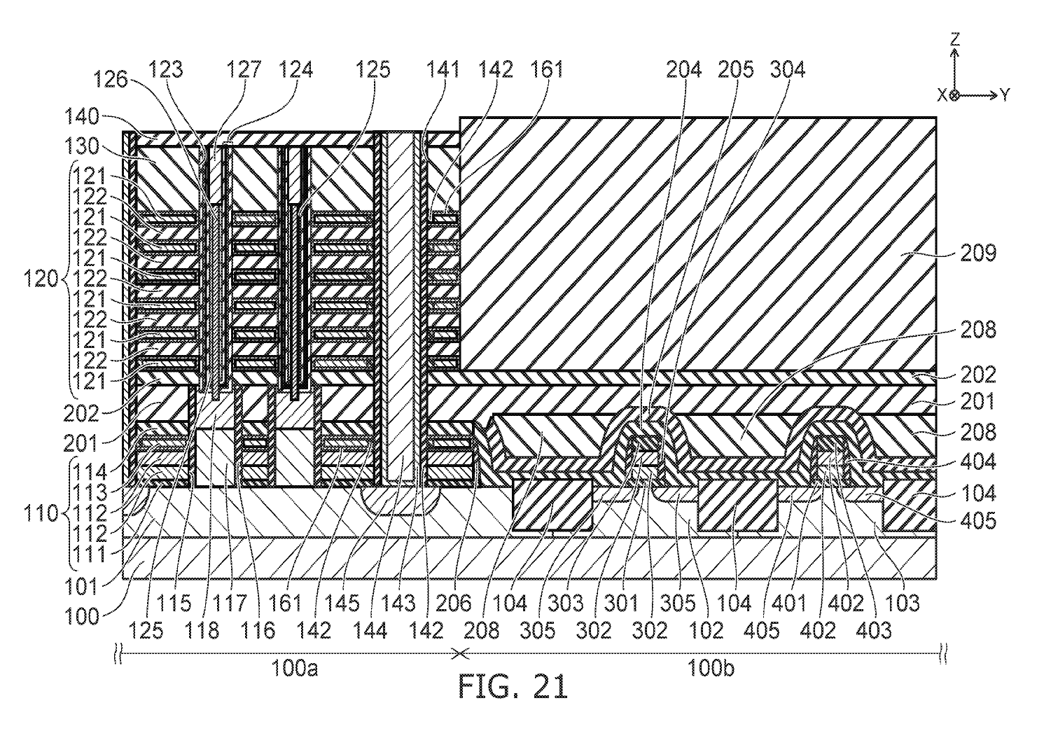

Next, as illustrated in FIG. 21, an insulating film 142 made from silicon nitride, for example, is formed on the inner surface of the through hole 141. Then, the insulating film 142 is removed from the bottom surface of the through hole 141 using an RIE process, for example, thereby exposing the n⁺ source layer 145. Next, a conductive film 143 made from a mixed material containing titanium and titanium nitride, for example, is formed on the inner side surfaces and bottom surface of the through hole 141. A conductive member 144 made from tungsten, for example, is then formed inside the through hole 141. The conductive member 144 is connected to the n⁺ source layer 145.

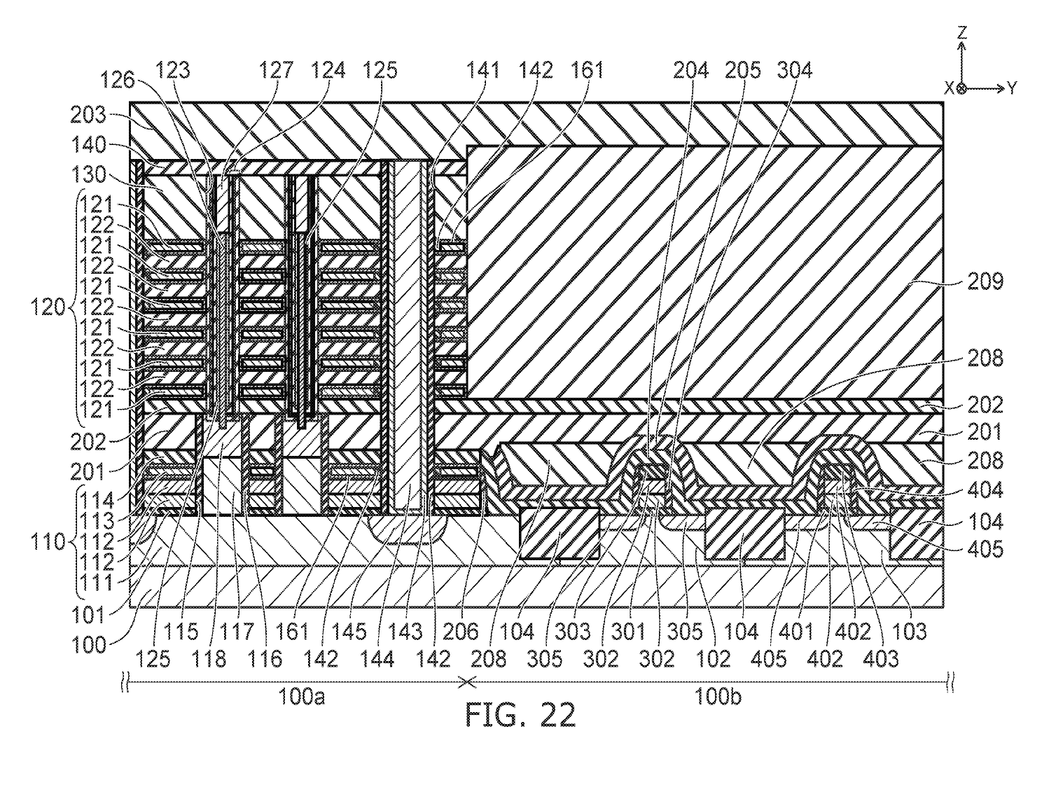

Next, as illustrated in FIG. 22, an insulating film 203 is formed across the entire cell region 100a and peripheral circuit region 100b and covers the insulating film 140 and the insulating member 209.

Next, as illustrated in FIG. 1 and FIG. 2, plugs 146 are formed directly above the through holes 123 in the cell region 100a. Each plug 146 goes through the insulating film 203 and the insulating film 140 and connects to the respective conductive member 127.

Moreover, a plug 151 is formed directly above the through hole 141. The plug 151 goes through the insulating film 203 and connects to the conductive member 144.

Furthermore, plugs 210 and 211 are formed in the peripheral circuit region 100b and go through the insulating film 203, the insulating member 209, the interlayer insulating films 202 and 201, and the insulating films 208, 205, and 204. The end of the plug 210 contacts the p⁺ region 305 provided in the cell region 100a side of the upper layer of the n-type diffusion layer 102. The plug 211 contacts the n⁺ region 405 provided in the cell region 100a side of the p-type diffusion layer 103.

In addition, plugs 171, 172, 173, 174, 175, 176, and 177 are formed connecting, respectively, to the X-direction end of the conductive layer 113 of the first stacked part 110 and the X-direction ends of the conductive layers 121 of the second stacked part 120. The plugs 171, 172, 173, 174, 175, 176, and 177 are connected to the ends of the conductive layers 111 and 121 that do not overlap when viewed from the Z-direction.

Moreover, the plug 171 goes through the insulating film 203, the insulating member 209, the interlayer insulating films 202 and 201, and the insulating layer 114 and connects to the end of the conductive layer 113. The plug 172 goes through the insulating film 203, the insulating member 209, and one of the insulating layers 122 and connects to the end of the lowermost conductive layer 121 of the first stacked part 110.

The plug 173 goes through the insulating film 203, the insulating member 209, and one of the insulating layers 122 and connects to the end of the conductive layer 121 one layer above the lowermost conductive layer 121 of the second stacked part 120. The plug 174 goes through the insulating film 203, the insulating member 209, and one of the insulating layers 122 and connects to the end of the conductive layer 121 two layers above the lowermost conductive layer 121 of the second stacked part 120. The plug 175 goes through the insulating film 203, the insulating member 209, and one of the insulating layers 122 and connects to the end of the conductive layer 121 three layers above the lowermost conductive layer 121 of the second stacked part 120. The plug 176 goes through the insulating film 203, the insulating member 209, and one of the insulating layers 122 and connects to the end of the conductive layer 121 four layers above the lowermost conductive layer 121 of the second stacked part 120. The plug 177 goes through the insulating film 203 and the insulating films 140 and 130 and connects to the end of the uppermost conductive layer 121 of the second stacked part 120.

The semiconductor memory device 1 is manufactured using the processes described above.

Next, the effects of the embodiment will be described.

In the embodiment, the insulating film 111 in the cell region 100a and the insulating films 301 and 401 in the peripheral circuit region 100b are all formed at once by creating divisions in the same insulating film 701 (see FIG. 3A). Moreover, the conductive layer 112 that forms a portion of a select gate electrode in the cell region 100a and the electrode films 302 and 402 in the peripheral circuit region 100b are all formed at once by creating divisions in the same conductive layer 702 (see FIG. 3A). This simultaneous formation can simplify the overall manufacturing process.

Furthermore, using multilayer structures for the select gate electrodes makes it possible to give those select gate electrodes longer gate lengths. This manufacturing method simultaneously reduces the cost of producing the semiconductor memory device and improves the cut-off characteristics of the device due to the longer gate lengths.

Furthermore, as illustrated in FIG. 5A, the lack of significant changes in elevation that could impede planarization facilitates easy completion of the CMP process on the upper portions of the cell region 100a and the peripheral circuit region 100b.

Moreover, inside the memory holes 115 that connect to the first stacked part 110, providing the semiconductor members 117 that are made from an intrinsic semiconductor material or a p-type semiconductor having a low impurity concentration next to the conductive layers 112 and 113 and then forming the conductive members 118 made from a silicon material that contains a high concentration of arsenic impurities, for example, as donors on top of those semiconductor members 117 can reduce parasitic resistance between the semiconductor members 117 and the semiconductor layers 125 in the cell region 100a.

Furthermore, the conductive layers 112 and 113 in the first stacked part 110 that function as select gate electrodes make it possible to use the surface of the semiconductor substrate 100 and the semiconductor members 117 as channel regions.

### Comparative Example

Next, a semiconductor memory device according to a comparative example will be described.

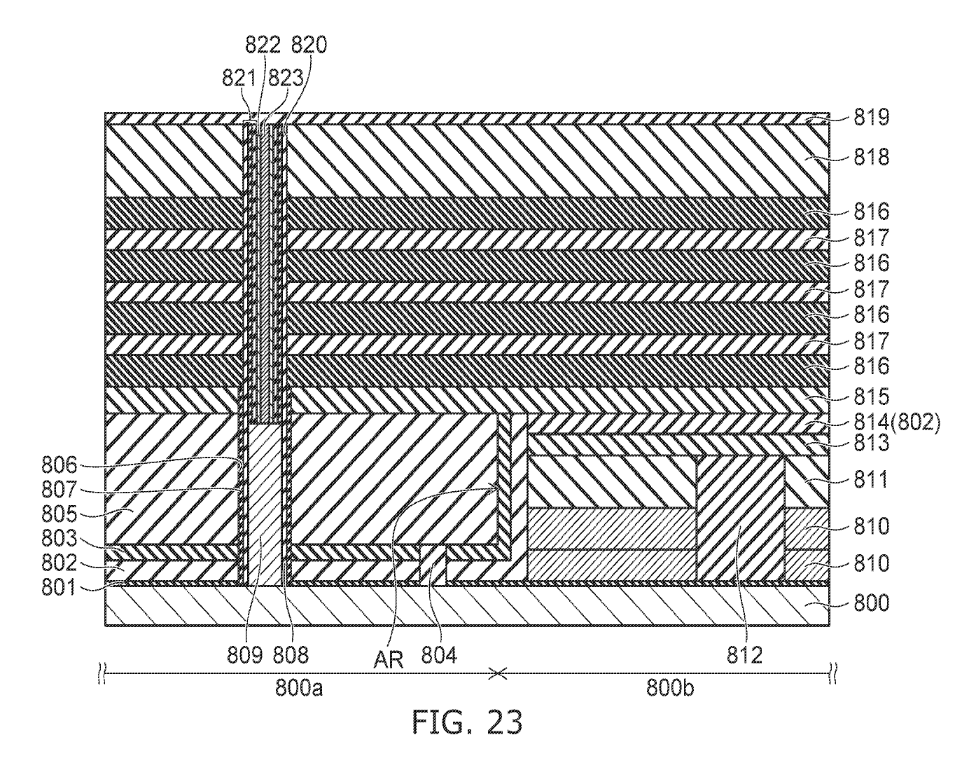

FIG. 23 is a cross-sectional view illustrating a semiconductor memory device according to the comparative example in one of the processes in a method for manufacturing the same.

As illustrated in FIG. 23, the semiconductor memory device according to the comparative example includes a semiconductor substrate 800 which is divided into two regions: a cell region 800a in which stacked memory cells are arranged and a peripheral circuit region 800b in which peripheral circuits are arranged.

An insulating film 801 is provided on top of the semiconductor substrate 100. In the cell region 800a, a silicon nitride layer 802 is provided on top of the insulating film 801. Moreover, a buffer layer 803 made from silicon oxide is provided on top of the silicon nitride layer 802. Furthermore, a device isolation film 804 is provided dividing the insulating film 801, the silicon nitride film 802, and the buffer layer 803. In addition, an insulating member 805 made from silicon oxide is provided on top of the buffer layer 803. Moreover, a memory hole 806 is formed going through the insulating member 805, the buffer layer 803, the silicon nitride film 802, and the insulating film 801. An insulating film 807 made from silicon oxide, for example, and a conductive film 808 made from silicon are formed, in order from the inner surface side, on the inner surface of the memory hole 806. A conductive member 809 is provided inside the memory hole 806.

In the peripheral circuit region 800b, two conductive films 810 made from silicon, for example, are provided on top of the insulating film 801. Also, an insulating film 811 made from silicon nitride is provided on top of the conductive films 810. Moreover, an insulating member 812 is provided in the peripheral circuit region 800b. The insulating member 812 divides the insulating film 811 and the two conductive films 810.

Furthermore, an insulating film 813 is provided on top of the insulating film 811 and the insulating member 812. In addition, the silicon nitride film 802 provided in the cell region 800a covers the side surfaces of the two conductive films 810 and the insulating films 811 and 813 as well as the top surface of the insulating film 813 provided in the peripheral circuit region 800b. Note that the portion of the insulating film 802 that covers the top surface of the insulating film 813 is referred to as the insulating film 814 to simplify the description. Furthermore, in the peripheral circuit region 100b, the buffer layer 803 covers the portion of the insulating film 802 that covers the side surfaces of the two conductive films 810 and the insulating films 811 and 813 as well as the side surface of the portion of the insulating film 802 that covers the top surface of the insulating film 813.

In addition, a silicon oxide film 815 is provided using a plasma CVD process on top of the insulating member 805 in the cell region 800a and on top of the silicon nitride film 802 provided on top of the insulating film 813 in the peripheral circuit region 800b. On top of this silicon oxide film, insulating films 816 made from silicon nitride, for example, and insulating films 817 made from silicon oxide, for example, are stacked in alternation. The combined number of insulating films 816 and 817 is eight, for example. An insulating film 818 made from silicon oxide, for example, is provided on top of the stacked assembly that includes the insulating films 816 and 817. Moreover, an insulating film 819 made from silicon oxide is provided on top of the insulating film 818.

A through hole 820 is formed directly above the memory hole 806. A silicon oxide-silicon nitride-silicon oxide film (an ONO film) 821 is provided on the inner surface of the through hole 820, and a conductive film 822 made from silicon is provided on top of the ONO film 821. A conductive member 823 is provided inside the through hole 820. The conductive member 823 is connected to the conductive member 809 provided inside the memory hole 806.

As illustrated by the arrow AR, the difference in height between the cell region 800a and the peripheral circuit region 800b is large in the comparative example. This difference causes the upper surface of the insulating member 815 to be recessed relative to the upper surface of the insulating film 814, which makes it difficult to planarize a large surface area in the CMP process. Moreover, the parasitic resistance in the cell region 800a is large due to the large distance between the lower select gate electrode and the control gate electrode. Furthermore, if the silicon nitride film 802 in the cell region 800a is replaced with a metal electrode in a later process, the select gate electrode can only be provided as a single layer. In this case, the gate length of the select gate electrode is short. This short gate length makes it more difficult to achieve satisfactory cut-off characteristics. In addition, the select gate electrode in the cell region 800a and the peripheral transistor in the peripheral circuit region 800b cannot both be formed at the same time in a single process. This increases the necessary number of manufacturing steps.

The embodiment as described above makes it possible to provide a semiconductor memory device in which production costs are reduced and in which parasitic resistance is small.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor memory device comprising:
a semiconductor substrate;
a first electrode film formed on the semiconductor substrate;
a second electrode film formed on the first electrode film;
a first semiconductor member going through the first electrode film;
a second semiconductor member going through the second electrode film and connected to the first semiconductor member;
a first insulating layer provided between the first electrode film and the first semiconductor member; and
a memory film provided between the second electrode film and the second semiconductor member and capable of storing charge,
the first electrode film including
a silicon layer and
a metal layer provided on the silicon layer.

2. The semiconductor memory device according to claim 1, further comprising:
a source layer and a drain layer formed separated from one another on the semiconductor substrate;
a gate insulating film provided directly above a portion of the semiconductor substrate between the source layer and the drain layer; and
a gate electrode provided on the gate insulating film,
a thickness of the gate electrode being equal to a thickness of the silicon layer,
a composition of the gate electrode being identical to a composition of the silicon layer,
a thickness of the second electrode film being equal to a thickness of the metal layer, and
a composition of the second electrode film being identical to a composition of the metal layer.

3. The semiconductor memory device according to claim 1, further comprising:
a conductive member connected between the first semiconductor member and the second semiconductor member.

4. The semiconductor memory device according to claim 1, further comprising:
a conductive member connected between the first semiconductor member and the second semiconductor member,
the conductive member being made of silicon containing an impurity, and
the first semiconductor member being made of silicon or silicon containing an impurity having a lower concentration than the conductive member.

5. The semiconductor memory device according to claim 1, further comprising:
a dielectric layer provided on a surface of the metal layer and having a greater dielectric constant than a dielectric constant of a silicon nitride film.

6. The semiconductor memory device according to claim 5, wherein the dielectric layer includes aluminum oxide.

7. The semiconductor memory device according to claim 1, further comprising:
a dielectric layer disposed around the second electrode.

8. The semiconductor memory device according to claim 1, wherein a surface of the semiconductor substrate and the first semiconductor member are used as channel regions because of effects of the first electrode.

9. A method for manufacturing a semiconductor memory device, comprising:
forming an insulating film on a semiconductor substrate;
forming a silicon layer on the insulating film;
forming a first layer on the silicon layer;
dividing a stacked body including the insulating film, the silicon layer, and the first layer into a first stacked body and a second stacked body by patterning;
forming a source layer and a drain layer in a region of the semiconductor substrate sandwiching the first stacked body;
forming a first through hole in the second stacked body;
forming a first insulating layer on a side surface of the first through hole;
forming a first semiconductor member on a side surface of the insulating layer;
forming a second stacked part on the first stacked body by alternately stacking second layers and second insulating layers;
forming, in the second stacked part, a second through hole communicating to the first through hole;
forming, on a side surface of the second through hole, a memory film capable of storing charge;
forming a second semiconductor member on a side surface of the memory film; and
replacing the first layer of the second stacked part and the second stacked body with a metal layer.

10. The method for manufacturing a semiconductor memory device according to claim 9, further comprising:
forming a stopper film covering the first stacked body and the second stacked body;
forming an interlayer insulating film on the stopper film; and
planarizing an upper surface of the interlayer insulating film using the stopper film as a stopper.
